(19) United States
(12) Patent Application Publication
(10) Pub. No.: US 2006/0292774 A1
(43) Pub. Date: Dec. 28, 2006

(54) Method for preventing metal line bridging in a semiconductor device

(75) Inventors: Lee-Jen Chen, Taipei City (TW); Chin-Ta Su, Erlun Shiang (TW); Chi-Tung Huang, Hsinchu (TW)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Macronix International Co., Ltd.

(21) Appl. No.: 11/166,230

(22) Filed: Jun. 27, 2005

(51) Int. Cl. H01L 21/8234

(52) U.S. Cl. 438/197

(57) ABSTRACT

A method for forming a semiconductor device includes providing a substrate, providing aluminum metal lines on the substrate, forming a barrier layer over the aluminum metal lines, and forming a silicon-rich dielectric layer over the barrier layer. An inter-metal dielectric (IMD) layer may be formed to cover at least a portion of the silicon-rich dielectric layer.

### FIELD OF THE INVENTION

This invention is in general related to a method of manufacturing semiconductor devices and, more particularly, to a method for resolving a metal line bridging issue and a device manufactured according to the method.

### BACKGROUND OF THE INVENTION

In semiconductor integrated circuits (ICs), metal lines are formed to provide contacts to individual elements of the ICs or to act as data lines. The deposition of such metal lines may result in an uneven surface. Thus, in a subsequent step to form a layer of inter-metal dielectric (IMD), a spin-on-glass (SOG) deposition process is routinely performed to result in an even surface.

FIG. 1 shows a semiconductor device 100, such as a memory device, including metal lines 102 formed on a substrate 10. Substrate 10 may be a semiconductor substrate including circuit elements formed thereon. An IMD layer 104 is formed over metal lines 102 and substrate 10 by depositing boro-phospho-silicate glass (BPSG) through an SOG process.

The SOG process for forming IMD layer 104 involves spinning onto substrate 10 having metal lines 102 formed thereon an SOG solution dissolving a mixture of SiO₂ and dopants (such as boron or phosphorous) and curing the SOG to evaporate the solvent in the solution. Because the solvent in the SOG solution may diffuse into the neighboring layers such as metal lines 102 during the curing process, the performance of semiconductor device 100 may be deteriorated. Accordingly, a liner layer 106 is provided between IMD 104 and metal lines 102 to prevent such diffusion of the SOG solvent, as shown in FIG. 1.

Conventionally, liner 106 comprises silicon dioxide (SiO₂), which may be formed by a plasma enhanced chemical vapor deposition (PECVD) process using a gas combination of SiH₄ and N₂O or a gas combination of tetraethylorthosilicate (TEOS) and O₂ or O₃. However, a problem with SiO₂ as oxide liner 106 is that, because the solvent dissolving the SOG used for forming IMD 104 contains a high concentration of hydrogen for achieving a low dielectric constant of IMD 104, the hydrogen atoms in the solvent may diffuse through liner 106 formed of SiO₂ into underlying layers such as metal lines 102 or substrate 10. As a result of the hydrogen diffusion, the performance of semiconductor device 100 is deteriorated.

U.S. Pat. No. 5,805,013 to Ghneim et al. discloses the release and diffusion of hydrogen atoms from their bonding sites in an SOG solvent used for forming an IMD layer whenever the hydrogen atoms are subjected to temperatures over a critical level. Ghneim et al. further discloses a method for reducing the hydrogen diffusion by keeping temperatures in all process steps subsequent to the SOG process below a critical temperature. Particularly, in Ghneim et al., hydrogen-containing dielectrics and all subsequent dielectrics/conductors are formed below 380° C., and in most instances below 350° C.

Although the low temperature processing steps disclosed in Ghneim et al. may reduce hydrogen diffusion, a reliability of the semiconductor device thus formed may nevertheless be deteriorated because of poor qualities of materials formed during the subsequent processing steps due to the low processing temperatures.

### SUMMARY OF THE INVENTION

Consistent with embodiments of the present invention, a method for forming a semiconductor device includes providing a substrate, providing aluminum metal lines on the substrate, forming a barrier layer over the aluminum metal lines, and forming a silicon-rich dielectric layer over the barrier layer.

Consistent with embodiments of the present invention, a semiconductor device includes a substrate, at least one aluminum metal line on the substrate, a barrier layer over the at least one aluminum metal line, and a silicon-rich dielectric layer over the barrier layer.

Additional features and advantages of the invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention.

In the drawings,

FIG. 1 shows a conventional semiconductor device using a liner layer;

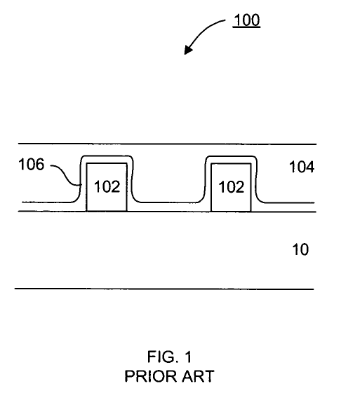

FIG. 2 shows a semiconductor device using a silicon-rich liner; and

FIG. 3 shows a semiconductor device consistent with embodiments of the present invention.

### DESCRIPTION OF THE EMBODIMENTS

Reference will now be made in detail to embodiments of the invention, examples of which are illustrated in the accompanying drawings. Wherever possible, the same reference numbers will be used throughout the drawings to refer to the same or like parts.

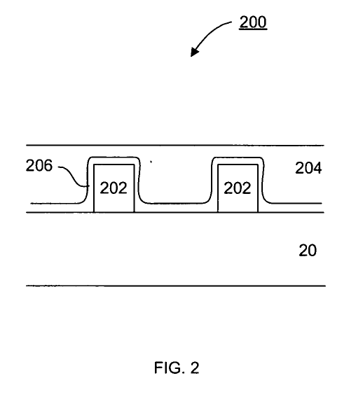

There has been proposed forming a silicon-rich oxide layer under an inter-metal dielectric (IMD) layer to act as a liner. FIG. 2 shows a semiconductor device 200 using such a silicon-rich oxide liner layer.

As shown in FIG. 2, semiconductor device 200 is formed on a substrate 20. Substrate 20 may be a semiconductor substrate including circuit elements formed thereon. Semiconductor device 200 includes metal lines 202 formed on substrate 20. An IMD layer 204 is formed over metal lines 202. IMD layer 204 may be formed by any conventional process such as an SOG process, a high density plasma (HDP) process, or a plasma enhanced chemical vapor deposition (PECVD) process.

A silicon-rich oxide liner layer 206 is provided between IMD layer 204 and metal lines 202. Silicon-rich oxide liner 206 may be formed by chemical vapor deposition (CVD) to comprise a silicon-rich oxide, wherein a ratio of the number of silicon atoms to the number of oxygen atoms in the silicon-rich oxide is higher than that in SiO₂, e.g., higher than 1:1. As a result, liner 206 contains a large number of dangling silicon bonds. If IMD layer 204 is formed by an SOG process, the dangling silicon bonds in liner 206 will capture and bond with hydrogen atoms in the solution of SOG and prevent the hydrogen atoms from entering into metal lines 202 and substrate 20. In such a case, it would be unnecessary to maintain a low temperature for subsequent processes. Liner 206 also prevents the diffusion of moisture or the solvent included in the SOG solution into metal lines 202 when IMD layer 204 is formed by an SOG process using the SOG solution, and protects metal lines 202 and substrate 20 from UV damage. Therefore, device 200 may achieve a satisfactory performance.

A potential problem with using silicon-rich liner 206 is that, when metal lines 202 are formed of aluminum, the aluminum diffuses into silicon-rich liner 206. If two adjacent metal lines 202 are close to each other, such aluminum diffusion may result in metal bridging, i.e., the two adjacent metal lines 202 are electrically short-circuited due to the aluminum diffused into liner 206.

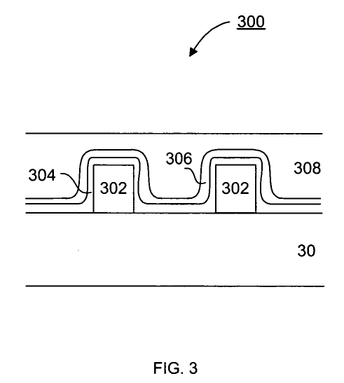

Consistent with embodiments of the present invention, a semiconductor device including an aluminum metal line covered by a silicon-rich liner further includes an aluminum barrier between the metal line and the silicon-rich liner. FIG. 3 shows a semiconductor device 300 consistent with embodiments of the present invention.

As shown in FIG. 3, semiconductor device 300 is formed on a substrate 30. Substrate 30 may be a semiconductor substrate including circuit elements formed thereon. Semiconductor device 300 includes aluminum metal lines 302 formed on substrate 30. A barrier 304 and a silicon-rich oxide liner layer 306 are sequentially formed over aluminum metal lines 302. An IMD layer 308 is formed over liner layer 306. IMD layer 308 may be formed by any conventional process such as an SOG process, an HDP process, or a PECVD process.

Barrier 304 prevents aluminum from diffusing into liner layer 306, and silicon-rich liner layer 306 prevents diffusion of hydrogen atoms, moisture, or the solvent included in an SOG solution into metal lines 302 when IMD 304 is formed by an SOG process using the SOG solution, and protects metal lines 302 and substrate 30 from UV damage. IMD layer 308 may cover a portion (not shown) or a whole of silicon-rich liner layer 306. Barrier 304 comprises an oxide or oxynitride, such as silicon oxide or silicon oxynitride, and may be formed using any suitable method known to one skilled in the art. In one aspect, silicon-rich liner 306 comprises a silicon-rich oxide, wherein a ratio of the number of silicon atoms to the number of oxygen atoms in the silicon-rich oxide is higher than that in SiO₂, e.g., higher than 1:1. In another aspect, liner 306 has a thickness of approximately 200-3000 Angstroms. Liner 306 may be formed using chemical vapor deposition (CVD) techniques such as plasma-enhanced CVD (PECVD) or high-density plasma chemical vapor deposition (HDPCVD), using a source gas combination of SiH₄ and O₂, SiH₄ and N₂O, TEOS and O₂, or TEOS and O₃. For example, liner 306 may be formed using a source gas combination of SiH₄ and O₂ mixed in Ar, in which flow rates of SiH₄, O₂, and Ar are respectively 100 sccm (standard cubic centimeters per minute), 50 sccm, and 50 sccm, and an RF power of the CVD is 3000 W.

It will be apparent to those skilled in the art that various modifications and variations can be made in the disclosed process without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for forming a semiconductor device, comprising:
providing a substrate;
providing aluminum metal lines on the substrate;
forming a barrier layer over the aluminum metal lines; and
forming a silicon-rich dielectric layer over the barrier layer.

2. The method of claim 1, wherein providing the substrate comprises:
providing a semiconductor substrate; and
forming circuit elements on the semiconductor substrate.

3. The method of claim 1, wherein forming the barrier layer comprises forming a layer of oxide or oxynitride.

4. The method of claim 1, wherein forming the silicon-rich dielectric layer comprises forming a silicon-rich oxide, such that a ratio of a concentration of silicon atoms to a concentration of oxygen atoms in the silicon-rich oxide is higher than 1:1.

5. The method of claim 1, wherein the silicon-rich dielectric layer is formed by chemical vapor deposition using at least one gas combination selected from a group consisting of a gas combination including SiH₄ and O₂, a gas combination including SiH₄ and N₂O, a gas combination including tetraethylorthosilicate (TEOS) and O₂, and a gas combination including TEOS and O₃.

6. The method of claim 1, further comprising forming an inter-metal-dielectric (IMD) layer over at least a portion of the silicon-rich dielectric layer.

7. A semiconductor device, comprising:
a substrate;
at least one aluminum metal line on the substrate;
a barrier layer over the at least one aluminum metal line; and
a silicon-rich dielectric layer over the barrier layer.

8. The device of claim 7, wherein the substrate is a semiconductor substrate having circuit elements formed thereon.

9. The device of claim 7, wherein the barrier layer comprises an oxide or an oxynitride.

10. The device of claim 7, wherein the silicon-rich dielectric layer comprises a silicon-rich oxide, and a ratio of a concentration of silicon atoms to a concentration of oxygen atoms in the silicon-rich oxide is higher than 1:1.

11. The device of claim 7, wherein the silicon-rich dielectric layer is formed by chemical vapor deposition using at least one gas combination selected from a group consisting of a gas combination including SiH₄ and O₂, a gas combination including SiH₄ and N₂O, a gas combination including tetraethylorthosilicate (TEOS) and O₂, and a gas combination including TEOS and O₃.

12. The device of claim 7, further comprising an inter-metal-dielectric (IMD) layer over at least a portion of the silicon-rich dielectric layer.
